(19) United States
(12) Patent Application Publication
(10) Pub. No.: US 2007/0113881 A1
(43) Pub. Date: May 24, 2007

(54) Method of making solar cell with antireflective coating using combustion chemical vapor deposition (CCVD) and corresponding product

(75) Inventors: Nathan P. Mellott, Northville, MI (US); Thomas J. Taylor, Northville, MI (US); Scott V. Thomsen, South Lyon, MI (US)

Correspondence Address: NIXON & VANDERHYE, PC, 901 NORTH GLEBE ROAD, 11TH FLOOR, ARLINGTON, VA, 22203, US

(73) Assignee: Guardian Industries Corp., Auburn Hills, MI (US)

(21) Appl. No.: 11/514,320

(22) Filed: Sep. 1, 2006

Related U.S. Application Data
(63) Continuation-in-part of application No. 11/284,424, filed on Nov. 22, 2005.
(60) Provisional application No. 60/802,800, filed on May 24, 2006.

(51) Int. Cl. H02N 6/00; C03C 17/00; H01L 25/00; H01L 31/00

(52) U.S. Cl. 136/243; 65/60.5; 65/60.8

(57) ABSTRACT

There is provided a coated article (e.g., solar cell) that includes an improved anti-reflection (AR) coating. This AR coating functions to reduce reflection of light from a glass substrate, thereby allowing more light within the solar spectrum to pass through the incident glass substrate. In certain example embodiments, the AR coating is at least partially formed by flame pyrolysis.

This application claims priority on Provisional Application No. 60/802,800, filed May 24, 2006, and is a continuation-in-part (CIP) of Ser. No. 11/284,424, filed Nov. 22, 2005, the disclosures of which are both hereby incorporated herein by reference.

This invention relates to a method of making a solar cell (or photovoltaic device) that includes an antireflective (AR) coating supported by a glass substrate. The AR coating is formed on a glass substrate or the like by way of flame pyrolysis, which is a type of combustion chemical vapor deposition (CCVD). An example of an AR coating is a CCVD-deposited layer of silicon oxide (e.g., SiO₂ or other suitable stoichiometry) on a glass substrate (directly or indirectly) at the light-incident side of a solar cell. Another example of an AR coating is an at least partially CCVD-deposited coating on such a glass substrate including a graded layer that includes a mixture of a metal oxide and silicon oxide (e.g., SiO₂ or other suitable stoichiometry).

### BACKGROUND OF THE INVENTION

Glass is desirable for numerous properties and applications, including optical clarity and overall visual appearance. For some example applications certain optical properties (e.g., light transmission, reflection and/or absorption) are desired to be optimized. For example, in certain example instances reduction of light reflection from the surface of a glass substrate (e.g., superstrate or any other type of glass substrate) is desirable for solar cells, and so forth.

Solar cells/modules are known in the art. Glass is an integral part of most common commercial photovoltaic modules (e.g., solar cells), including both crystalline and thin film types. A solar cell/module may include, for example, a photoelectric transfer film made up of one or more layers located between a pair of substrates. One or more of the substrates may be of glass. The glass may form a superstrate, protecting underlying device(s) and/or layer(s) for converting solar energy to electricity. Example solar cells are disclosed in U.S. Pat. Nos. 4,510,344, 4,806,436, 6,506,622, 5,977,477, and JP 07-122764, the disclosures of which are hereby incorporated herein by reference.

Substrate(s) in a solar cell/module are sometimes made of glass. Incoming radiation passes through the incident glass substrate of the solar cell before reaching the active layers (e.g., photoelectric transfer film such as a semiconductor) of the solar cell. Radiation that is reflected by the incident glass substrate does not make its way into the active layer(s) of the solar cell thereby resulting in a less efficient solar cell. In other words, it would be desirable to decrease the amount of radiation that is reflected by the incident glass substrate, thereby increasing the amount of radiation that makes its way to the active layer(s) of the solar cell. In particular, the power output of a solar cell or photovoltaic module is dependant upon the amount of light, or number of photons, within a specific range of the solar spectrum that pass through the incident glass substrate and reach the photovoltaic semiconductor.

AR coatings have been used on the fronts of solar cells. However, typical AR coatings are formed by sputtering or the like, and are thus undesirable from the point of view of cost and complexity. It would be desirable if a more efficient and cost effective AR coating could be applied with respect to solar cell applications.

Thus, it will be appreciated that there exists a need for an improved AR coating, for solar cells or other applications, to reduce reflection off of glass substrates.

### BRIEF SUMMARY OF EXAMPLE EMBODIMENTS OF THE INVENTION

In certain example embodiments of this invention, an improved anti-reflection (AR) coating is provided on an incident glass substrate of a solar cell or the like, and a method of making the same. This AR coating functions to reduce reflection of light from the glass substrate, thereby allowing more light within the solar spectrum to pass through the incident glass substrate and reach the photovoltaic semiconductor so that the solar cell can be more efficient. In certain example embodiments, the AR coating is formed on the glass substrate via flame pyrolysis (a type of combustion chemical vapor deposition (CCVD)). When the flame pyrolysis deposited AR coating is used in combination with a high transmission low-iron light incident glass, the advantages are especially significant.

The flame-pyrolysis-deposited AR coating may include or be of, a layer of or including silicon oxide (e.g., SiO₂) on a glass substrate (directly or indirectly with other layer(s) therebetween) in certain example embodiments of this invention.

In other example embodiments of this invention, the AR coating may include a graded layer that includes a mixture of titanium oxide (e.g., TiO₂ or other suitable stoichiometry), or other metal oxide, and silicon oxide (e.g., SiO₂ or other suitable stoichiometry). In certain example embodiments, the graded layer includes a greater amount of silicon oxide at the side of the graded layer closest to the glass substrate than at a side of the graded layer further from the glass substrate. Moreover, in certain example embodiments, the graded layer includes a greater amount of titanium oxide (or other metal oxide) at a side of the graded layer further from the glass substrate than at a side of the graded layer closer to the glass substrate. An additional type of coating such as silicon oxide or the like may be provided over the graded layer in certain example embodiments. Thus, it is possible to provide an AR coating on a glass substrate using a combination of both graded refractive index and destructive interference approaches. In certain example embodiments, where the graded layer, having a graded or varying refractive index (n), is deposited via CCVD on the glass (directly or indirectly) where the composition profile varies from predominately SiO₂ near the glass surface to a higher index material predominately TiO₂ (or other metal oxide) further from the glass surface, one can effectively change the refractive index (n) of the “glass” surface to about 2.0-2.5, or possibly 2.3-2.5. Then, an optional layer of CCVD-formed SiO₂ at about a ¼ wave thickness (from about 100 nm) deposited on top of the graded layer may act as a destructive interference coating and hence be antireflective. The optional layer of SiO₂ may have a physical thickness of from about 50 to 150 nm, more preferably from about 80 to 140 nm, still more preferably from about 80 to 130 nm, more preferably from about 100 to 130 nm, and possibly about 100 or 125 nm in certain example embodiments so as to represent a ¼ wave thickness.

In certain example embodiments, there is provided a method of making a solar cell, the method comprising: providing a photovoltaic layer and at least a glass substrate on a light incident side of the photovoltaic layer; providing an anti-reflection coating provided on the glass substrate, the anti-reflection coating including at least one layer and being located on a light-incident side of the glass substrate; and wherein flame pyrolysis is used to form at least part of the anti-reflection coating which is provided on the light-incident side of the glass substrate of the solar cell.

In other example embodiments of this invention, there is provided a solar cell, comprising: a photovoltaic layer and at least a glass substrate on a light incident side of the photovoltaic layer; an anti-reflection coating for at least partially by flame pyrolysis provided on the glass substrate, the anti-reflection coating including at least one layer and being located on a light-incident side of the glass substrate; and wherein the glass substrate is low iron and comprises:

| Ingredient | wt. % |
|---|---|
| SiO₂ | 67-75% |
| Na₂O | 10-20% |
| CaO | 5-15% |
| total iron (expressed as Fe₂O₃) | 0.001 to 0.06% |
| cerium oxide | 0 to 0.30% |

wherein the glass substrate by itself has a visible transmission of at least 90%, a transmissive a* color value of −1.0 to +1.0 and a transmissive b* color value of from 0 to +1.5.

### BRIEF DESCRIPTION OF THE DRAWINGS

FIG. 1(a) is a cross sectional view of a solar cell including an antireflective (AR) coating according to an example embodiment of this invention.

FIG. 1(b) is a cross sectional view of a solar cell including an antireflective (AR) coating according to another example embodiment of this invention.

FIG. 2 is a cross sectional view of a solar cell that may use the AR coating of FIG. 1(a) or 1(b) according to an example embodiment of this invention.

### DETAILED DESCRIPTION OF EXAMPLE EMBODIMENTS OF THE INVENTION

Referring now more particularly to the accompanying drawings in which like reference numerals indicate like parts throughout the several views.

Certain example embodiments of this invention relate to a method of making a solar cell (or photovoltaic device) that includes an antireflective (AR) coating supported by a glass substrate. The AR coating is formed on a glass substrate or the like by way of flame pyrolysis, which is a type of combustion chemical vapor deposition (CCVD). In certain example embodiments of this invention, an improved anti-reflection (AR) coating is provided on an incident glass substrate of a solar cell or the like. This AR coating functions to reduce reflection of light from the glass substrate, thereby allowing more light within the solar spectrum to pass through the incident glass substrate and reach the photovoltaic semiconductor so that the solar cell can be more efficient. The glass substrate may be a glass superstrate or any other type of glass substrate in different instances.

Certain example embodiments of this invention relate to the use of an AR silica inclusive or based coating 3 deposited via flame pyrolysis on a low-iron float or patterned glass substrate 1, for use in solar cell or other photovoltaic applications. In particular, the glass substrate may be the cover glass on the light-incident side of a solar cell. The low-iron glass 1 in combination with the flame pyrolysis deposited AR coating 3 decrease the amount of radiation that is reflected or absorbed by the incident glass substrate, thereby increasing the amount of radiation that makes its way to the active layer(s) of the solar cell. In particular, the power output of a solar cell or photovoltaic module is dependant upon the amount of light, or number of photons, within a specific range of the solar spectrum that pass through the incident glass substrate and reach the photovoltaic semiconductor, so that the use of low-iron high transmission glass 1 in combination with the flame pyrolysis deposited AR coating 3 significantly increases the amount of photons reaching the photovoltaic semiconductor of the solar cell thereby improve its functionality.

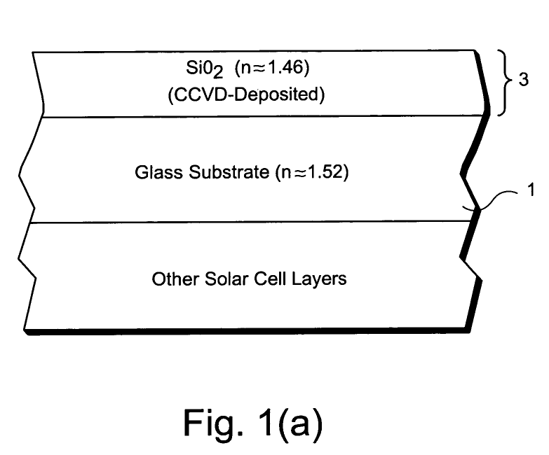

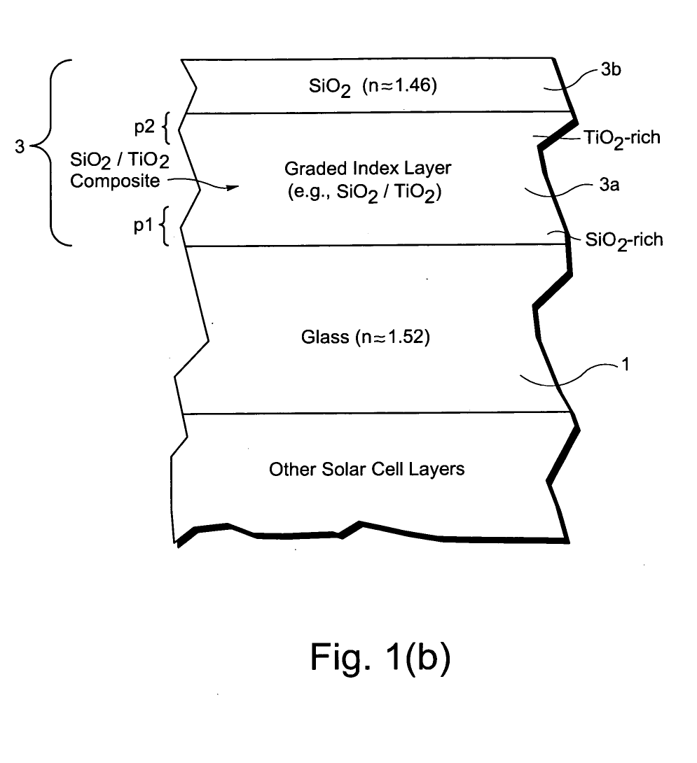

FIG. 1(a) is a cross sectional view of a coated article according to an example embodiment of this invention, which may be used in a solar cell or the like. The solar cell of FIG. 1 includes a light-incident side glass substrate 1 and an AR coating 3. The AR coating 3 in this particular embodiment includes or is made up of a layer of or including silicon oxide (e.g., SiO₂, or other suitable stoichiometry).

Still referring to FIG. 1(a), flame pyrolysis is used to deposit the AR coating 3 which is of or including silicon oxide. In flame pyrolysis, for example, a silane gas such as HDMSO or TEOS may be fed into at least one burner (or flame of the burner) in order to cause a layer of silicon oxide 3 to be deposited on glass substrate 1 at approximately atmospheric pressure. Alternatively, the flame pyrolysis may utilize a liquid and/or gas including Si or other desirable material being fed into the flame of at least one burner. In flame pyrolysis examples, a silicon precursor is thermally and/or hydrolytically decomposed, via addition of a combustible gas (e.g., Butane and/or propane) and deposited on the substrate from the gaseous phase. Examples of flame pyrolysis are disclosed in, for example and without limitation, U.S. Pat. Nos. 3,883,336, 4,600,390, 4,620,988, 5,652,021, 5,958,361, and 6,387,346, the disclosures of all of which are hereby incorporated herein by reference.

The use of flame pyrolysis to deposit AR coating 3 is advantageous for a number of reasons. Flame pyrolysis is much cheaper and less capital intensive than sputter or the like. Moreover, when flame pyrolysis is used to deposit AR coating 3, the exterior surface of flame pyrolysis deposited layer 3 may have a degree of roughness defined by peaks and valleys (i.e., nanostructures) therein. The peaks may be sharp or significantly rounded in different embodiments of this invention, as may the valleys. The roughness of the exterior surface of layer 3 is defined by the elevations “d” of peaks relative to adjacent valleys, and by the gaps between adjacent peaks or adjacent valleys. On the surface of layer 3, the average elevation value “d” in certain embodiments is from about 5-60 nm, more preferably from about 10-50 nm, and most preferably from about 20-35 nm. On the surface of layer 3, the average gap distance “g” between adjacent peaks or adjacent valleys in certain embodiments is from about 10-80 nm, more preferably from about 20-60 nm, and most preferably from about 20-50 nm. Such roughness caused by the flame pyrolysis technique (i.e., structural peaks and valleys) may be randomly distributed across the surface of the flame pyrolysis layer 3 in certain embodiments, and may be approximately uniformly distributed in other embodiments. Importantly, this roughness caused by the flame pyrolysis allows good light transmission through the light incident glass 1 (with coating 3 thereon) because the nanostructures (e.g., peaks and valleys) are smaller than certain wavelengths of visible light so that the light is not substantially scattered as it passes therethrough. In certain example instances, the use of flame pyrolysis and thus the surface roughness of layer 3 also enhances hydrophobicity of the coating which may be desirable in certain instances. Thus, it will be appreciated that the use of flame pyrolysis for depositing at least part of the AR coating 3 is advantageous with respect to other possible techniques.

In the FIG. 1(a) embodiment, the AR coating is made up entirely of the silicon oxide based layer 3. However, in other example embodiments, other layer(s) may be provided on the glass substrate 1 above and/or below the AR layer of the FIG. 1(a) embodiment; e.g., see the FIG. 1(b) embodiment.

FIG. 1(b) is a cross sectional view of a coated article according to another example embodiment of this invention. The coated article of FIG. 1(b) includes a glass substrate 1 and an AR coating 3. The AR coating of the FIG. 1(b) embodiment includes a graded layer 3a and an overcoat layer 3b. The graded layer 3a may be graded with respect to its material and/or refractive index (n) value. In the FIG. 1(b) embodiment, the graded layer 3a includes a mixture of a titanium oxide (e.g., TiO₂ or other suitable stoichiometry, such as TiOₓ where x is from 1.0 to 2.0) (or other metal oxide) and silicon oxide (e.g., SiO₂ or other suitable stoichiometry, such as SiOₓ where x is from 1.0 to 2.0). In certain example embodiments, the graded layer 3a includes a greater amount of a silicon oxide at a side of the graded layer 3a closest to the glass substrate 1 than at a side of the graded layer 3a further from the glass substrate 1. Moreover, in certain example embodiments, the graded layer 3a includes a greater amount of titanium oxide at a side of the graded layer 3a further from the glass substrate 1 than at a side of the graded layer 3a closer to the glass substrate 1. This graded layer 3a may be deposited by flame pyrolysis in certain example embodiments of this invention, although it alternatively may be deposited by sputtering or the like.

Still referring to the FIG. 1(b) embodiment, in certain example embodiments of this invention, the portion p1 of the graded layer 3a closest to the glass substrate 1 is predominately made up of silicon oxide (e.g., SiO₂), and the portion p2 of the graded layer 3a furthest from the glass substrate 1 is predominately made up of titanium oxide (e.g., TiO₂) or other metal oxide. In certain example embodiments of this invention, the portion p1 of the graded layer 3a closest to the glass substrate 1 is from about 40-100% silicon oxide (e.g., SiO₂), more preferably from about 50-100%, even more preferably from about 70-100% and most preferably from about 80-100% silicon oxide (with the remainder being made up of titanium oxide or some other material). In certain example embodiments of this invention, the portion p2 of the graded layer 3a furthest from the glass substrate 1 is from about 40-100% titanium oxide (e.g., TiO₂), more preferably from about 50-100%, even more preferably from about 70-100% and most preferably from about 80-100% titanium oxide (with the remainder being made up of silicon oxide or some other material). In certain example embodiments of this invention, the portions p1 and p2 of the graded layer 3a may contact each other near the center of the layer, whereas in other example embodiments of this invention the portions p1 and p2 of the graded layer 3a may be spaced apart from each other via an intermediately portion of the graded layer 3a that is provided at the central portion of the graded layer as shown in FIG. 1(b).

With respect to the FIG. 1(b) embodiment, in certain example embodiments of this invention, the refractive index (n) value of the graded layer 3a varies throughout its thickness, with the refractive index (n) being less at the portion of layer 3a closest to the glass substrate 1 and greater at the portion of the layer 3a furthest from the glass substrate 1. In certain example embodiments of this invention, the refractive index value of the near portion p1 of the graded layer 3a closest to the glass substrate may be from about 1.46 to 1.9, more preferably from about 1.46 to 1.8, even more preferably from about 1.46 to 1.7, and most preferably from about 1.46 to 1.6. The near portion p1 of the layer 3a may be from about 5 to 10,000 Å thick, possibly from about 10 to 500 Å thick, in certain example embodiments of this invention. In certain example embodiments of this invention, the refractive index value of the far portion p2 of the graded layer 3a farthest from the glass substrate 1 may be from about 1.8 to 2.55, more preferably from about 1.9 to 2.55, even more preferably from about 2.0 to 2.55, even more preferably from about 2.0 to 2.25. The far portion p2 of the layer 3a may be from about 5 to 10,000 Å thick, possibly from about 10 to 500 Å thick, in certain example embodiments of this invention. It has been found that the use of titanium (Ti) oxide in the graded layer 3a is particularly advantageous in that it permits a high refractive index value to be possible in the outer portion p2 of the graded layer 3a, thereby improving antireflective properties of the AR coating. As mentioned above, the graded layer 3a may be deposited on the glass substrate 1 in any suitable manner. For example, the graded layer 3a may be deposited by sputtering in certain example embodiments. In certain example instances, the layer may be sputter-deposited by initially sputter-depositing several layers in a sequence with varying ratios of silicon oxide to titanium oxide; then the resulting sequence of layers could be heat treated (e.g., 250 to 900 degrees C.). To deposit this sequence of layers initially, targets of Si, SiAl, Ti, and/or SiTi could be used. For example, a Si or SiAl sputtering target(s) in an oxygen and argon gaseous atmosphere could be used to sputter-depositing the bottom layer(s) of the sequence, a Ti sputtering target(s) in an oxygen and argon gaseous atmosphere could be used to sputter-deposit the top layer(s) of the sequence, and a Si/Ti target(s) in an oxygen and argon atmosphere could be used to sputter-deposit the intermediate layer(s) of the sequence. The diffusion profile or composition profile would be controlled by the heat treatment time and temperature that the sequence was subjected to so as to result in a graded layer 3a. However, heat treatment need not be used. Other techniques for forming the graded layer 3a could instead be used, such as CCVD. The graded layer 3a may be any suitable thickness in certain example embodiments of this invention. However, in certain example embodiments, the graded layer 3a has a thickness of at least one wavelength of light. Moreover, the refractive index (n) value and/or material composition of the graded layer 3a may vary throughout the layer in either a continuous or non-continuous manner in different example embodiments of this invention.

The graded layer uses titanium oxide as a high index material in the FIG. 1(b) embodiment. However, it is noted that Zr may be used to replace or supplement the Ti in the FIG. 1(b) embodiment in certain alternative embodiments of this invention. In still further example embodiments, Al may be used to replace or supplement the Ti in the FIG. 1(b) embodiment in certain alternative embodiments of this invention.

In the FIG. 1(b) embodiment, antireflective layer 3b of or including a material such as silicon oxide (e.g., SiO₂) or the like may be provided over the graded layer 3a via flame pyrolysis in certain example embodiments of this invention as shown in FIG. 1(b) for example. In certain example embodiments, the thickness of the overcoat antireflective layer 3b is approximately ¼ wave thickness (quarter wave thickness plus/minus about 5 or 10%) so as to act as a destructive interference coating/layer thereby reducing reflection from the interface between layers 3a and 3b. When the quarter wave thickness layer 3b is composed of SiO₂ at about a ¼ wave thickness, then the layer 3b will have a physical thickness of from about 50 to 150 nm, more preferably from about 80 to 140 nm, still more preferably from about 80 to 130 nm, and most preferably from about 100 to 130 nm, and possibly about 100 or 125 nm in certain example embodiments so as to represent a ¼ wave thickness. While silicon oxide is preferred for destructive interference layer 3b in certain example embodiments, it is possible to use other materials for this layer 3b in other example embodiments of this invention. When other materials are used for layer 3b, the layer 3b may also have an approximate quarter wave thickness in certain example embodiments of this invention. Silicon oxide inclusive layer 3b may be relatively dense in certain example embodiments of this invention; e.g., from about 75-100% hardness, for protective and/or optical purposes. It is noted that it is possible to form other layer(s) over layer 3b in certain example instances, although in many embodiments the layer 3b is the outermost layer of the AR coating 3.

It is noted that silicon oxide of layer 3, 3a and/or 3b may be doped with other materials such as aluminum, nitrogen or the like. Likewise, the titanium oxide of layer 3a may be doped with other material(s) as well in certain example instances.

In certain example embodiments of this invention, high transmission low-iron glass may be used for glass substrate 1 in order to further increase the transmission of radiation (e.g., photons) to the active layer of the solar cell or the like, in one or both of the FIG. 1(a) and FIG. 1(b) embodiments. For example and without limitation, the glass substrate 1 may be of any of the glasses described in any of U.S. patent application Ser. Nos. 11/049,292 and/or 11/122,218, the disclosures of which are hereby incorporated herein by reference.

Certain glasses for glass substrate 1 (which or may not be patterned in different instances) according to example embodiments of this invention utilize soda-lime-silica flat glass as their base composition/glass. In addition to base composition/glass, a colorant portion may be provided in order to achieve a glass that is fairly clear in color and/or has a high visible transmission. An exemplary soda-lime-silica base glass according to certain embodiments of this invention, on a weight percentage basis, includes the following basic ingredients:

EXAMPLE BASE GLASS

| Ingredient | Wt. % |
|---|---|
| SiO₂ | 67-75% |
| Na₂O | 10-20% |
| CaO | 5-15% |
| MgO | 0-7% |
| Al₂O₃ | 0-5% |
| K₂O | 0-5% |
| Li₂O | 0-1.5% |
| BaO | 0-1% |

Other minor ingredients, including various conventional refining aids, such as SO₃, carbon, and the like may also be included in the base glass. In certain embodiments, for example, glass herein may be made from batch raw materials silica sand, soda ash, dolomite, limestone, with the use of sulfate salts such as salt cake (Na₂SO₄) and/or Epsom salt (MgSO₄×7H₂O) and/or gypsum (e.g., about a 1:1 combination of any) as refining agents. In certain example embodiments, soda-lime-silica based glasses herein include by weight from about 10-15% Na₂O and from about 6-12% CaO.

In addition to the base glass above, in making glass according to certain example embodiments of the instant invention the glass batch includes materials (including colorants and/or oxidizers) which cause the resulting glass to be fairly neutral in color (slightly yellow in certain example embodiments, indicated by a positive b* value) and/or have a high visible light transmission. These materials may either be present in the raw materials (e.g., small amounts of iron), or may be added to the base glass materials in the batch (e.g., cerium, erbium and/or the like). In certain example embodiments of this invention, the resulting glass has visible transmission of at least 75%, more preferably at least 80%, even more preferably of at least 85%, and most preferably of at least about 90% (sometimes at least 91%) (Lt D65). In certain example non-limiting instances, such high transmissions may be achieved at a reference glass thickness of about 3 to 4 mm In certain embodiments of this invention, in addition to the base glass, the glass and/or glass batch comprises or consists essentially of materials as set forth in Table 2 below (in terms of weight percentage of the total glass composition):

EXAMPLE ADDITIONAL MATERIALS IN GLASS

| Ingredient | General (Wt. %) | More Preferred | Most Preferred |
|---|---|---|---|
| total iron | 0.001-0.06% | 0.005-0.04% | 0.01-0.03% |
| (expressed as | | | |
| Fe₂O₃): | | | |
| cerium oxide: | 0-0.30% | 0.01-0.12% | 0.01-0.07% |
| TiO₂ | 0-1.0% | 0.005-0.1% | 0.01-0.04% |
| Erbium oxide: | 0.05 to 0.5% | 0.1 to 0.5% | 0.1 to 0.35% |

In certain example embodiments, the total iron content of the glass is more preferably from 0.01 to 0.06%, more preferably from 0.01 to 0.04%, and most preferably from 0.01 to 0.03%. In certain example embodiments of this invention, the colorant portion is substantially free of other colorants (other than potentially trace amounts). However, it should be appreciated that amounts of other materials (e.g., refining aids, melting aids, colorants and/or impurities) may be present in the glass in certain other embodiments of this invention without taking away from the purpose(s) and/or goal(s) of the instant invention. For instance, in certain example embodiments of this invention, the glass composition is substantially free of, or free of, one, two, three, four or all of: erbium oxide, nickel oxide, cobalt oxide, neodymium oxide, chromium oxide, and selenium. The phrase “substantially free” means no more than 2 ppm and possibly as low as 0 ppm of the element or material. It is noted that while the presence of cerium oxide is preferred in many embodiments of this invention, it is not required in all embodiments and indeed is intentionally omitted in many instances. However, in certain example embodiments of this invention, small amounts of erbium oxide may be added to the glass in the colorant portion (e.g., from about 0.1 to 0.5% erbium oxide).

The total amount of iron present in the glass batch and in the resulting glass, i.e., in the colorant portion thereof, is expressed herein in terms of Fe₂O₃ in accordance with standard practice. This, however, does not imply that all iron is actually in the form of Fe₂O₃ (see discussion above in this regard). Likewise, the amount of iron in the ferrous state (Fe⁺²) is reported herein as FeO, even though all ferrous state iron in the glass batch or glass may not be in the form of FeO. As mentioned above, iron in the ferrous state (Fe²⁺; FeO) is a blue-green colorant, while iron in the ferric state (Fe³⁺) is a yellow-green colorant; and the blue-green colorant of ferrous iron is of particular concern, since as a strong colorant it introduces significant color into the glass which can sometimes be undesirable when seeking to achieve a neutral or clear color.

It is noted that the light-incident surface of the glass substrate 1 may be flat or patterned in different example embodiments of this invention.

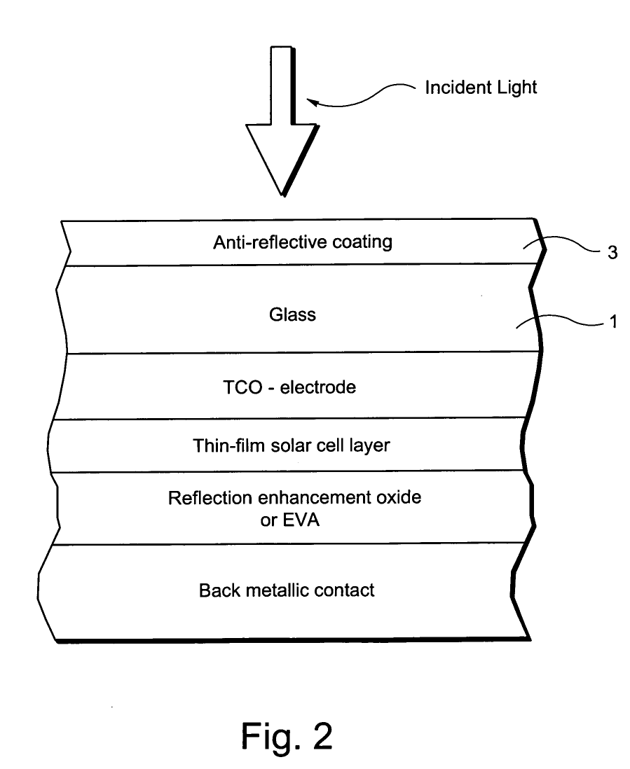

FIG. 2 is a cross-sectional view of a solar cell or photovoltaic device, for converting light to electricity, according to an example embodiment of this invention. The solar cell of FIG. 2 uses the AR coating 3 and glass substrate 1 shown in FIG. 1(a) or FIG. 1(b) in certain example embodiments of this invention. The incoming or incident light is first incident on AR coating 3, passes therethrough and then through low-iron high transmission glass substrate 1 before reaching the photovoltaic semiconductor of the solar cell (see the thin film solar cell layer in FIG. 2). Note that the solar cell may also include, but does not require, an electrode such as a transparent conductive oxide (TCO), a reflection enhancement oxide or EVA film, and/or a back metallic contact as shown in example FIG. 2. Other types of solar cells may of course be used, and the FIG. 2 solar cell is merely provided for purposes of example and understanding. As explained above, the AR coating 3 reduces reflections of the incident light and permits more light to reach the thin film semiconductor layer of the solar cell thereby permitting the solar cell to act more efficiently.

While certain of the AR coatings 3 discussed above are used in the context of the solar cells/modules, this invention is not so limited. AR coatings according to this invention may be used in other applications such as for picture frames, fireplace doors, and the like. Also, other layer(s) may be provided on the glass substrate under the AR coating so that the AR coating is considered on the glass substrate even if other layers are provided therebetween. Also, while the graded layer 3a is directly on and contacting the glass substrate 1 in the FIG. 1(b) embodiment, it is possible to provide other layer(s) between the glass substrate and the graded layer in alternative embodiments of this invention.

While the invention has been described in connection with what is presently considered to be the most practical and preferred embodiment, it is to be understood that the invention is not to be limited to the disclosed embodiment, but on the contrary, is intended to cover various modifications and equivalent arrangements included within the spirit and scope of the appended claims.

1. A method of making a solar cell, the method comprising:
providing a photovoltaic layer and at least a glass substrate on a light incident side of the photovoltaic layer;
providing an anti-reflection coating provided on the glass substrate, the anti-reflection coating including at least one layer and being located on a light-incident side of the glass substrate; and
wherein flame pyrolysis is used to form at least part of the anti-reflection coating which is provided on the light-incident side of the glass substrate of the solar cell.

2. The method of claim 1, wherein the flame pyrolysis is used to form the anti-reflection coating at approximately atmospheric pressure, where the anti-reflection coating comprises SiO₂.

3. The method of claim 1, wherein the flame pyrolysis comprises causing a silane, liquid and/or gas, to be fed into at least one burner and/or flame in order to cause a layer comprising silicon oxide to be deposited on the glass substrate as at least part of the anti-reflection coating.

4. The method of claim 3, wherein the silane comprises TEOS and/or HDMSO.

5. The method of claim 1, wherein the flame pyrolysis is used to form a layer comprising SiO₂ on the glass substrate.

6. The method of claim 5, wherein another layer is provided on the glass substrate between the glass substrate and the layer comprising SiO₂.

7. The method of claim 1, wherein the anti-reflection coating includes a graded layer provided directly on and contacting the glass substrate, the graded layer including a mixture of silicon oxide and titanium oxide, with more titanium oxide being provided in a far portion of the graded layer farther from the glass substrate than in a near portion of the graded layer closer to the glass substrate; and
wherein the anti-reflection coating further comprises a layer comprising silicon oxide located over the graded layer, at least the layer comprising silicon oxide being deposited via the flame pyrolysis.

8. The method of claim 7, wherein the near portion of the graded layer has a refractive index less than that of the far portion of the graded layer.

9. The method of claim 7, where the near portion of the graded layer is made up of predominately silicon oxide.

10. The method of claim 7, wherein the near portion of the graded layer has a refractive index value of from about 1.46 to 1.9.

11. The method of claim 7, wherein the near portion of the graded layer has a refractive index value of from about 1.46 to 1.7, wherein the titanium oxide is TiO₂ and the silicon oxide is SiO₂.

12. The method of claim 7, wherein the far portion of the graded layer has a refractive index value of from about 2.0 to 2.55.

13. The method of claim 7, wherein the far portion of the graded layer has a refractive index value of from about 2.3 to 2.55.

14. The method of claim 7, wherein the far portion of the graded layer is made up predominately of titanium oxide.

15. The method of claim 7, wherein the layer comprising silicon oxide has approximately a quarter wave thickness.

16. The method of claim 7, wherein the layer comprising silicon oxide is from about 80 to 140 nm thick.

17. The method of claim 7, wherein the near portion of the graded layer is made up of from about 40-100% silicon oxide and the far portion of the graded layer is made up of from about 50-100% titanium oxide.

18. The method of claim 7, wherein the near portion of the graded layer is made up of from about 70-100% silicon oxide and the far portion of the graded layer is made up of from about 70-100% titanium oxide.

19. A method of claim 1, wherein the anti-reflection coating comprises a graded layer including a mixture of silicon oxide and a metal (M) oxide, with more metal (M) oxide being provided in a far portion of the graded layer farther from the glass substrate than in a near portion of the graded layer closer to the glass substrate, and wherein M is one or more of the group of Ti, Zr and Al; and wherein the anti-reflection coating further comprises a layer comprising silicon oxide located over the graded layer.

20. The method of claim 1, wherein the glass substrate comprises:

| Ingredient | wt. % |
|---|---|
| SiO₂ | 67-75% |
| Na₂O | 10-20% |
| CaO | 5-15% |
| total iron (expressed as Fe₂O₃) | 0.001 to 0.06% |
| cerium oxide | 0 to 0.30% |

wherein the glass substrate by itself has a visible transmission of at least 90%, a transmissive a* color value of −1.0 to +1.0 and a transmissive b* color value of from 0 to +1.5.

21. A solar cell, comprising:
a photovoltaic layer and at least a glass substrate on a light incident side of the photovoltaic layer;
an anti-reflection coating for at least partially by flame pyrolysis provided on the glass substrate, the anti-reflection coating including at least one layer and being located on a light-incident side of the glass substrate; and
wherein the glass substrate comprises:

| Ingredient | wt. % |
|---|---|
| SiO₂ | 67-75% |
| Na₂O | 10-20% |
| CaO | 5-15% |
| total iron (expressed as Fe₂O₃) | 0.001 to 0.06% |
| cerium oxide | 0 to 0.30% |

wherein the glass substrate by itself has a visible transmission of at least 90%, a transmissive a* color value of −1.0 to +1.0 and a transmissive b* color value of from 0 to +1.5.
